(19) United States
(12) Patent Application Publication
(10) Pub. No.: US 2025/0253117 A1
(43) Pub. Date: Aug. 7, 2025

(54) Sample Holding Tool, Electron Ray Device, and Manufacturing Method for Sample Holding Tool

(71) Applicant: Hitachi, Ltd., Chiyoda-ku, Tokyo (JP)

(72) Inventors: Akira SUGAWARA, Tokyo (JP); Toshiaki TANIGAKI, Tokyo (JP)

(21) Appl. No.: 18/838,270

(22) PCT Filed: Mar. 15, 2022
(86) PCT No.: PCT/JP2022/011744

§ 371 Date: Apr. 16, 2025

(51) Int. Cl. H01J 37/20

(52) U.S. Cl. CPC H01J 37/20; H01J 2237/2003

(57) ABSTRACT

The present invention has as its object the provision of a sample holder, which can internally have a plurality of spaces enclosed by separating membranes. The sample holder according to the present invention includes a dividing member dividing an internal space into a first space and a second space, and also includes a sealing material layer arranged above an upper limit of the first space (see FIG. 1).

### TECHNICAL FIELD

The present invention relates to a sample holder including a space for holding a sample.

### BACKGROUND ART

Toward realization of carbon neutrality, there is a growing demand in recent years for techniques that, concerning environment friendly functional materials such as catalysts and electrodes for practicalizing fuel cells, secondary batteries, hydrogen-compatible structures, artificial photosyntheses, and so on, analyze their structures, electric fields, and/or magnetic fields at an atomic level during their reactions in a liquid or a gas under environmental control. Environmental transmission electron microscopy is a technique that seals a liquid film or gas film transparent to an electron beam and a sample as an object of observation in a sample holder called a “separating-membrane-type environmental cell” and observes a reaction of the sample in the liquid or gas. Electron holography is a measuring method derived from transmission electron microscopy and is a technique that measures the phase of an electron beam by using interference effects between an object wave passed through a sample and a reference wave passed through a vacuum.

Non Patent Document 1 describes a separating-membrane-type environmental cell that, in a vacuum chamber of a transmission electron microscope, two separating membranes of silicon nitride are facing each other via a spacer layer, and a liquid or a gas is fed and enclosed in an interstice so formed.

Patent Document 1 describes a technique relating to a sample support structure. This document includes a description that reads: “The present invention discloses a novel reinforced thin membrane structure with integrated support features, and methods of fabrication for this structure. The structure provides a larger region membrane with support features that subdivide the large membrane into smaller regions. This structure offers the sample viewing region of a large, thin membrane with the strength of individual smaller membranes.” (Paragraph [0003])

### PRIOR ART DOCUMENTS

### Patent Document

Patent Document 1: JP-2013-228403-A

### Non Patent Document

Non Patent Document 1: F. Wu, N. Yao, Advances in windowed gas cells for in-situ TEM studies, Nano Energy. 13 (2015) 735-756.

### SUMMARY OF THE INVENTION

### Problems to be Solved by the Invention

Patent Document 1 subdivides a region to enhance the strength of a separating membrane, and is believed not to fully explicitly consider forming a plurality of spaces enclosed with separating membranes. To form a plurality of spaces enclosed with separating membranes in a sample holder, there is a need to cover the spaces with a sealing layer and then to bond and fix the sealing layer. Patent Document 1 however does not disclose any specific manner for meeting this need.

As an example of techniques for observing behavior of a sample enclosed in a separating-membrane-type environmental cell by irradiating the sample with an electron beam, there is electron holography. In electron holography, it is desired to use, as a reference wave, an electron beam traveled in a vacuum without passing through a sample. A sample holder, which holds a sample to be observed using electron holography, is therefore desired to arrange a vacuum region in a vicinity of a space that holds the sample. In the separating-membrane-type environmental cell described in Non Patent Document 1, however, only a single enclosed space is formed, so that no vacuum region is believed to exist in a vicinity of a sample (even if it exists, it is in a region apart to some extent from the sample and outside of the separating-membrane-type environmental cell). It is hence difficult to perform electron holography using the separating-membrane-type environmental cell described in Non Patent Document 1. Even if performed, no practical precision is considered to be available as a reference wave has a high noise level.

With the foregoing problems in view, the present invention has as an object thereof the provision of a sample holder, which can internally have a plurality of spaces enclosed by separating membranes.

### Means for Solving the Problems

A sample holder according to the present invention includes a dividing member dividing an internal space into a first space and a second space, and also includes a sealing material layer arranged above the first space.

### Advantages of the Invention

With the sample holder according to the present invention, a plurality of spaces enclosed by separating membranes can be internally included. Other configurations, objects, advantages, and the like of the present invention will become apparent by the following description of embodiments.

### BRIEF DESCRIPTION OF THE DRAWINGS

FIG. 1 is a side cross-sectional view depicting a configuration example of a separating-membrane-type cell 100 according to Embodiment 1.

FIG. 2 is an overhead view of the separating-membrane-type cell 100 obtained as a result of bonding.

FIG. 3 is a cross-sectional view of a sample support system of the configuration of FIG. 1 enclosed with a liquid or a gas and a solid object of observation filled in sample holding pockets.

FIG. 4 is a top view depicting a flow channel configuration in a separating-membrane-type cell 100 according to Embodiment 2.

FIG. 5 is a side cross-sectional view of the separating-membrane-type cell 100 according to Embodiment 2.

FIG. 6 illustrates a manner for fixing the separating-membrane-type cell 100 to a sample holder 500.

FIG. 7 is a side cross-sectional view depicting a configuration example of a separating-membrane-type cell 100 according to Embodiment 3.

FIG. 8 is a configuration diagram of a transmission electron microscope that is observing a sample using the separating-membrane-type cell 100 according to Embodiment 3.

### MODES FOR CARRYING OUT THE INVENTION

### Embodiment 1

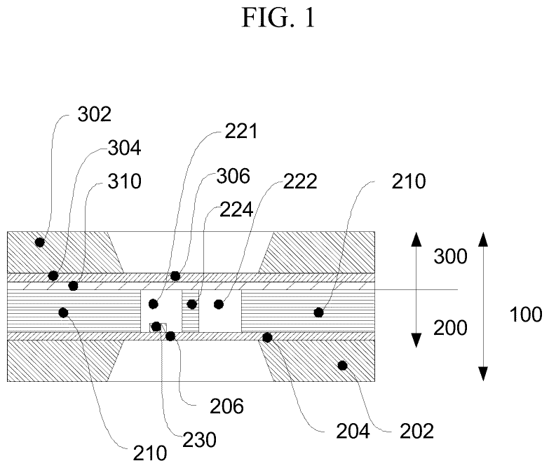

FIG. 1 is a side cross-sectional view depicting a configuration example of a separating-membrane-type cell 100 according to Embodiment 1 of the present invention. The separating-membrane-type cell 100 can be configured as a sample holder to enclose therein a sample to be observed using, for example, a transmission electron microscope.

A lower chip 200 includes a lower silicon frame 202, a lower separating membrane 204, and a spacer layer 210. About a heater 230, a description will be made subsequently herein. On a silicon wafer, a separating membrane material is typically formed to a thickness of 200 nm or smaller by vapor phase growth. The material that forms the separating membrane material is typically a low-stress silicon nitride thin membrane formed by a chemical vapor phase growth method. However, another thin-membrane material that has high mechanical strength and allows an electron beam to transmit therethrough may also be used. By forming a mask over a back surface of the silicon wafer and then selectively back-etching the silicon wafer, a lower separating membrane window 206 is formed with the lower separating membrane 204 exposed at both front and back surfaces. Undissolved portions of the silicon wafer assure mechanical strength as the lower silicon frame 202. The spacer layer 210 is formed over the front surface of the lower separating membrane 204. As in-plane structures of the spacer layer 210, two or more sample pockets (in FIG. 1, a first sample holding pocket 221 and a second sample holding pocket 222) are formed in a portion corresponding to the lower separating membrane window 206. The sample pockets are portions recessed from a front surface of the spacer layer 210. Choosing silicon or a metal species having high adhesion to the lower separating membrane 204 and low chemical activity, the spacer layer 210 is formed by lift-off lithography or the like. As an alternative, a resist layer with the first sample holding pocket 221 and the second sample holding pocket 222 formed therein may be left as it is, if the resist layer has sufficient chemical and thermal durability against a liquid or gas to be loaded. The thickness of the spacer layer 210 defines an interval between the lower separating membrane window 206 and an upper separating membrane window 306, in other words, an electron beam transparent thickness for the liquid or gas to be loaded. The width of an inter-pocket partition in the spacer layer 210 defines the distance between the first sample holding pocket 221 (first space) and the second sample holding pocket 222 (second space).

An upper chip 300 has an upper silicon frame 302 and an upper separating membrane 304. The upper separating membrane window 306 is formed in a similar manner as in the case of the lower chip 200. The lower separating membrane window 206 and the upper separating membrane window 306 are not absolutely needed to be coincident in size in a rigorous manner.

An enclosed structure having the two sample holding spaces can be fabricated in the following procedures. Over a front surface of the upper separating membrane 304, a photo-curing resin layer 310 is applied thin by such a technique as spin coating. After bringing the lower chip 200 and the upper chip 300 into alignment such that the lower separating membrane window 206 and the upper separating membrane window 306 coincide in position with each other, the front surface of the spacer layer 210 on a side of the lower chip 200 and the photo-curing resin layer 310 on a side of the upper chip 300 are placed facing each other, and are compression-bonded together under a pressure at which the separating membranes are not damaged, followed by irradiation of light such as ultraviolet light, so that the photo-curing resin layer 310 is solidified. FIG. 1 is a cross-sectional view of the enclosed structure fabricated in the foregoing procedures, in which only gas is contained in the first sample holding pocket 221 and the second sample holding pocket 222.

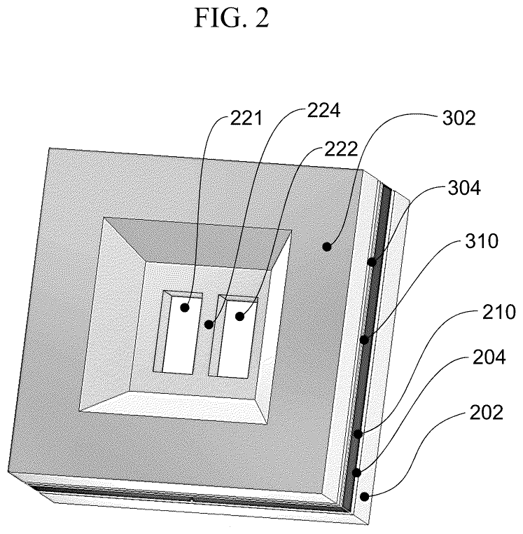

FIG. 2 is an overhead view of the separating-membrane-type cell 100 obtained as a result of the bonding. It can be easily confirmed by such a technique as optical microscopy through the upper separating membrane window 306 whether the separating-membrane-type cell 100 is configured including two or more sample holding pockets.

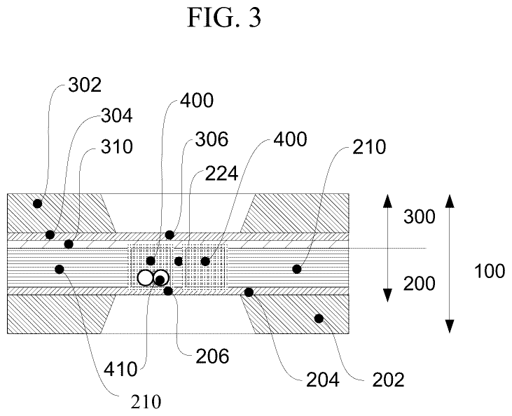

FIG. 3 is a cross-sectional view of a sample support system of the configuration of FIG. 1 enclosed with the liquid or gas and a solid object of observation filled in the sample holding pockets. The heater 230 is omitted for the convenience of illustration. In an environmental transmission microscopic observation, the lower chip 200 and the upper chip 300 of the above-described configurations are supplied individually as components. In principle, an end user loads a solid sample 410 and a liquid or gas 400. The first sample holding pocket 221 and the second sample holding pocket 222 are filled with the solid sample 410 and the liquid or gas 400. As in the case of the structure depicted in FIG. 1, the photo-curing resin layer 310 is applied thin by such a technique as spin coating over the upper separating membrane 304, and the lower chip 200 and the upper chip 300 are bonded together by photopolymerization. This enables enclosure of the solid sample 410 and the gas or liquid 400 in the first sample holding pocket 221 and the second sample holding pocket 222.

The thickness of the spacer layer 210 defines the interval between the lower separating membrane window 206 and the upper separating membrane window 306, in other words, the electron beam transparent thickness for the liquid or gas to be loaded. The width of an inter-pocket partition 224 in the spacer layer 210 defines the distance between the first sample holding pocket 221 and the second sample holding pocket 222. The lower separating membrane window 206 and the upper separating membrane window 306 are not absolutely needed to be coincident in size. The solid sample 410 includes, for example, a metal catalyst, a ceramic carrier, or the like for generation of hydrogen or reduction of carbon dioxide. If the highly corrosive gas or liquid 400 is strongly alkaline or acidic or has a strong acidifying or reducing property, use of such a noble metal material as gold or platinum or a ceramic material as a material for the spacer layer 210 is desired.

To deal, as an object of research, with behavior of a material under heated or electrified conditions, it is sufficient if a sample-heating microheater or bias voltage electrodes are formed beforehand with metal on the lower separating membrane 204 below the first sample holding pocket 221 and the second sample holding pocket 222, an insulating and protective layer is formed on the sample-heating microheater or bias voltage electrodes, and then the spacer layer 210 is formed on the insulating and protective layer. The heater 230 is an example of a heating member formed as described above.

The configuration of the separating-membrane-type cell 100 according to Embodiment 1 seals the liquid or gas 400 and the solid sample 410 by curing the photo-curing resin layer 310. The sample can therefore be observed by a normal-type sample holder without using such a sealing mechanism as O-rings for a sample holder of a special structure.

### Embodiment 1: Summary

The sample holder according to Embodiment 1 includes a plurality of enclosed spaces (the first sample holding pocket 221 and the second sample holding pocket 222) sealed by separating membranes owing to the bonding of the upper silicon frame 302 and the lower silicon frame 202 with use of the photo-curing resin layer 310. This allows an electron beam or the like to pass through a sample, thereby enabling an observation of the sample. Moreover, a different observation can be performed for each enclosed space. This enables to test a plurality of different combinations of observation conditions faster than providing a plurality of sample holders and replacing them. This feature is advantageous compared with such a structure that individual sample holding pockets are simply covered by a lid member without being sealed, because the content of one of the sample holding pockets may spill toward another or other sample holding pockets if they are simply covered by the lid member.

In Embodiment 1, the bonding of the upper silicon frame 302 and the lower silicon frame 202 with use of the photo-curing resin layer 310 is described. There is a significance in that the sample holder, which allows transmission of an electron beam or the like therethrough, is formed by bonding together the upper and lower frames in which portions of thin membranes are exposed owing to the respective formation of the upper separating membrane window 306 and the lower separating membrane window 206. It should be noted that, in this regard, Embodiment 1 is different from a general manufacturing process in which substrates are bonded together simply using photo-curing resin.

### Embodiment 2

In Embodiment 2 of the present invention, a description will be made about a configuration in which a liquid or a gas can be supplied to sample holding pockets or exhausted from the sample holding pockets, instead of forming simple enclosed spaces by sealing the first sample holding pocket 221 and the second sample holding pocket 222 with the lower separating membrane 204 and the upper separating membrane 304 in the separating-membrane-type cell 100.

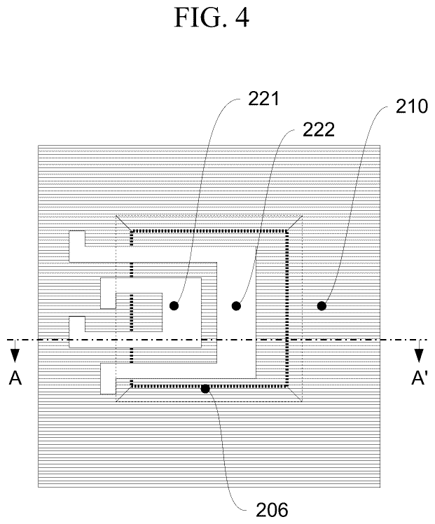

FIG. 4 is a top view depicting a flow channel configuration in a separating-membrane-type cell 100 according to Embodiment 2. In Embodiment 2, a first sample holding pocket 221 and a second sample holding pocket 222 also serve as flow channels for a liquid or gas 400. In the example of this two-compartment configuration, two inlets and two outlets are needed.

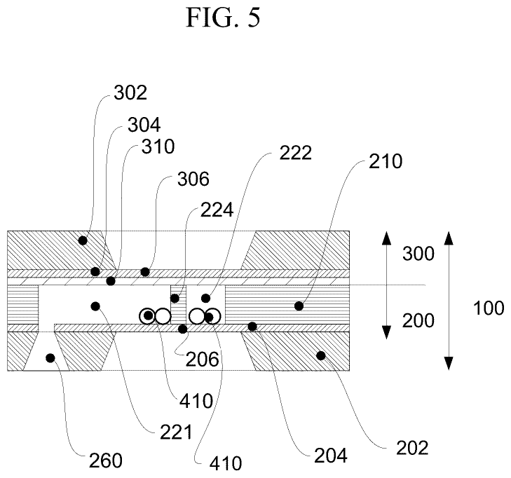

FIG. 5 is a side cross-sectional view of the separating-membrane-type cell 100 according to Embodiment 2. FIG. 5 depicts a section A-A′ of FIG. 4. With solid samples 400 placed in the first sample holding pocket 221 and the second sample holding pocket 222, a lower chip 200 and an upper chip 300 are bonded together beforehand by photopolymerization as in Embodiment 1. A flow channel 260 is formed in a lower silicon frame 202 by chemical etching, plasma etching, or the like. The flow channel 260 therefore brings a lower surface of the lower silicon frame 202 and the first sample holding pocket 221 into communication with each other. As the flow channel 260 is formed in the lower silicon frame 202, the separating-membrane-type cell 100 does not have an enclosed structure yet at this time point.

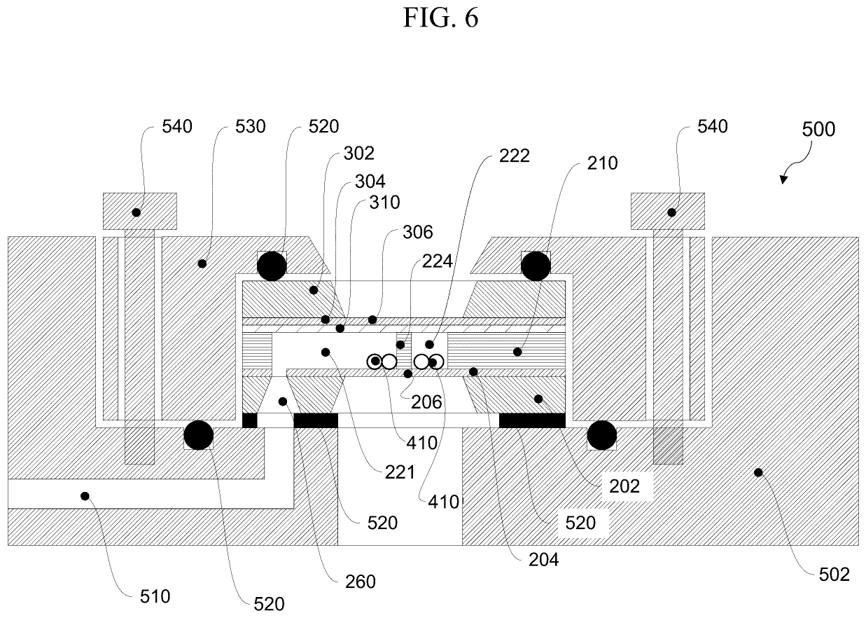

FIG. 6 illustrates a manner for fixing the separating-membrane-type cell 100 to a sample holder 500. A cell holding plate 530 is fixed to a sample holder frame with use of fixing screws 540, whereby the separating-membrane-type cell 100 is fixed to the sample holder 500. In the sample holder frame 502, four liquid or gas inlet tubes 510 are formed beforehand in this case. With outlets of the liquid or gas inlet tubes 510 and the positions of the flow channels 260 coincided with each other, the cell holding plate 530 is fixed to the sample holder frame 502, so that vacuum sealing with vacuum sealing packings 520 is established. Accordingly, flows of the liquid or gas 400 supplied from the outside of vacuum are supplied to the enclosed first sample holding pocket 221 and second sample holding pocket 222 through the liquid or gas inlet tubes 510 and the flow channels 260, and are then allowed to return to the outside of vacuum through the flow channels 260 and the liquid or gas inlet tubes 510, both, as return paths. The sample holder 500 and the separating-membrane-type cell 100 may be considered in combination to be a sample holder in a broad sense.

### Embodiment 3

In Embodiments 1 and 2, the samples can be held using the sample holders according to the present disclosure and observed, for example, under an electron microscope. As another application of the sample holders according to the present disclosure, it is contemplated to observe samples by electron holography. In Embodiment 3 of the present disclosure, a description will be made about the configuration of a sample holder for the observation by electron holography and the configuration of a transmission electron microscope that uses the sample holder.

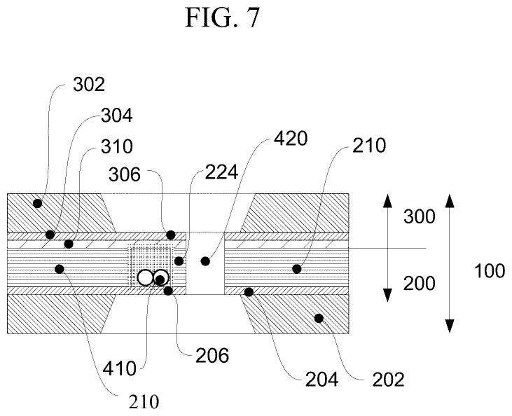

FIG. 7 is a side cross-sectional view depicting a configuration example of a separating-membrane-type cell 100 according to this Embodiment 3. With a conventional separating-membrane-type cell, it is difficult to determine a potential field around a solid sample in a liquid or a gas on the basis of a phase measurement of an electron beam by electron holography. In Embodiment 3, a first sample holding pocket 221 is filled with a solid sample 410 and a gas or liquid 400, and the portion of a second sample holding pocket 222 is used as a bore for allowing an undisturbed electron beam to pass therethrough. When the separating-membrane-type cell 100 is arranged in a sample chamber of the transmission electron microscope, the portion of the second sample holding pocket 222 is hence brought into a vacuum state, and an electron beam passes through this vacuum portion accordingly.

The first sample holding pocket 221 of a lower chip 200 is first filled with the solid sample 410 and the gas or liquid 400. The second sample holding pocket 222 is filled with a gas without the solid sample 410 placed therein. As filling work is generally performed under a clean environment of normal pressure, the second sample holding pocket 222 is naturally filled with the gas. Here, the gas in the second sample holding pocket 222 may be atmospheric air.

As in Embodiment 1, the lower chip 200 and an upper chip 300 are bonded together via a photo-curing resin layer 310 to fabricate an enclosed structure. The resulting integrated structure is introduced into a focused ion beam processing (FIB) system or a focused ion beam-scanning electron microscope (FIB-SEM) combined system, and only the upper and lower separating membranes arranged above and below the second sample holding pocket 222 are removed by focused ion beam etching. Especially when a spacer layer 210 is formed with metal, the position of the second sample holding pocket 222 can be readily deduced from a secondary electron image, thereby enabling determination with ease of a region to be irradiated with a focused ion beam. The second sample holding pocket 222 loses the function to seal the liquid or gas 400 due to the removal of the upper and lower separating membranes, and therefore serves as a vacuum bore 420 where the electron beam travels through a vacuum without being scattered.

Taking advantage of this characteristic, the electron beam transmitted through the liquid or gas 400 and the solid sample 410 enclosed in the first sample holding pocket 221 is used as an object wave 610, whereas an electron beam 612 traveled through the second sample holding pocket 222 (in other words, the vacuum bore 420) and having an undisturbed wave front is used as a reference wave. Interference fringes can be formed by superposing the two waves using an electron biprism 608 (to be mentioned below). In other words, a potential field formed around the solid sample 410 in the liquid or gas 400 can be determined using electron holography.

As an excessive interference region of the electron beam is at most on the order of micrometers, the width of an inter-pocket partition 224 between the first sample holding pocket 221 and the vacuum bore 420 (the second sample holding pocket 222 before the removal of the separating membranes) is desirably two micrometers or smaller. In principle, a structure similar to that of FIG. 7 can also be formed by accurately aligning a lower separating membrane window 206 and an upper separating membrane window 306 to each other and bonding them together, with openings formed in the respective windows. Under an optical microscope, however, no alignment is practically possible with an accuracy of one micrometer or smaller. Embodiment 3 has an advantage in that the formed position of the vacuum bore 420 is defined beforehand as the position of the second sample holding pocket 222, and the accuracy of the bonding between the lower chip 200 and the upper chip 300 may be coarse.

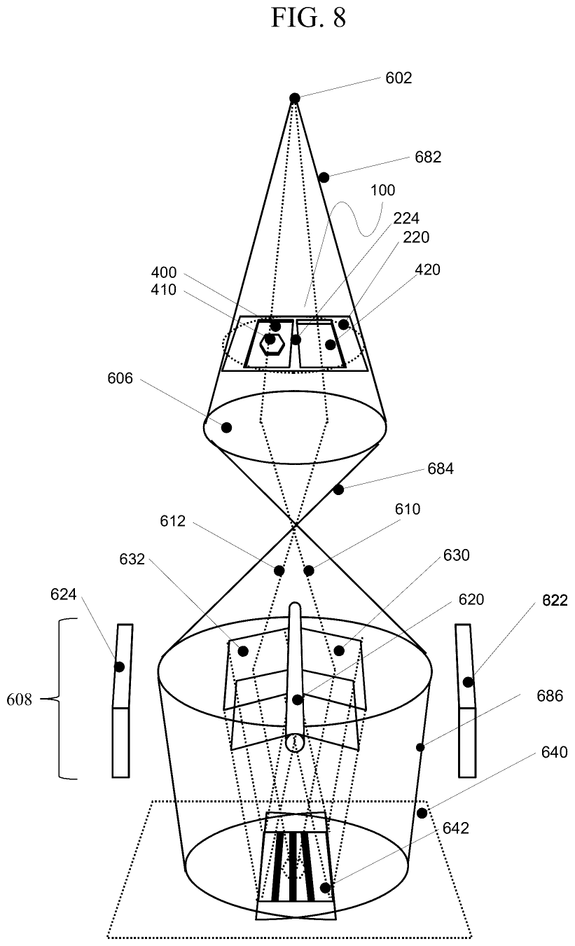

FIG. 8 is a configuration diagram of a transmission electron microscope that is observing a sample using the separating-membrane-type cell 100 according to Embodiment 3. In this example, the sample that is held using the separating-membrane-type cell 100 is measured by electron holography. In FIG. 8, the lower silicon frame 202, the lower separating membrane 204, the upper silicon frame 302, the upper separating membrane 304, and the photo-curing resin layer 310 are omitted for the simplification of illustration.

An electron beam generated at an electron source 602 travels with a certain solid angle, passes through the separating-membrane-type cell 100, an objective lens 606, and the electron biprism 608, and reaches a detection surface of a detector 640. Regions through which the electron beam passes in the course of this travel are indicated by a circular cone 682, circular cones 684, and a truncated circular cone 686. The separating-membrane-type cell 100 is arranged in the circular cone 682, through which the electron beam passes, between the electron source 602 and the objective lens 606. An object wave passes through each of the upper separating membrane 304, the photo-curing resin layer 310, the solid sample 410 and gas or liquid 400 filled in the first sample holding pocket 221, and the lower separating membrane 204. A reference wave passes through the vacuum bore 420. The object wave changes in phase according to the internal potential of the material, which forms the material, or the electric field and/or magnetic field. The reference wave undergoes no phase change. After this electron beam has passed through the objective lens 606, the electron beam converges once and then diverges again as indicated by the circular cones 684. A typical path of the object wave is indicated by a dotted line 610, and a typical path of the reference wave is indicated by a dotted line 612.

The electron beam next passes through the electron biprism 608. The electron biprism 608 includes an electron biprism wire 620, which is made from a conductive microwire of one micron or smaller in width and is applied with a positive potential, and a combination of grounded opposite electrodes 622 and 624. As electric fields are created between the electron biprism wire 620 and the opposite electrodes 622 and 624, the electron beams that pass through these regions are subjected to deflection by Coulomb force, and the directions of deflection are opposite on right and left sides of the electron biprism wire 620. The wave front of the electron beam is therefore divided into two zones with different inclinations. An inclined object wave front 630 and an inclined reference wave front 632 progressively overlap with each other as they advance, and form electron beam interference fringes 642 on the detector 640. The phase of the electron beam can be determined by subjecting the interference fringes to a Fourier analysis.

As the arrangement of the electron biprism 608, a configuration is possible in which a plurality of electron biprisms is arranged downstream of the objective lens 606, or another configuration is also possible in which one biprism is arranged upstream of the sample and a plurality of electron biprisms is further arranged downstream of the sample.

To use interference effects of the reference wave in Embodiment 3, the vacuum bore 420 is desirably at a distance of approximately several hundreds of nanometers relative to the solid sample 410, with a distance of approximately two micrometers at maximum being desired. The sample holder of the present disclosure enables this distance by the inclusion of the first sample holding pocket 221 and the second sample holding pocket 222 (the vacuum bore 420). It is hence possible to enable a behavior observation by electron holography of the solid sample 410 in the gas or liquid 400, although such a behavior observation by electron holography has been difficult with conventional separating-membrane-type environmental cells as in Non Patent Document 1.

To irradiate the electron beam in a symmetrical shape in Embodiment 3, the first sample holding pocket 221 and the second sample holding pocket 222 are preferably configured in a symmetrical shape to each other with respect to the inter-pocket partition 224.

### Embodiment 3: Summary

The sample holder according to Embodiment 3 allows the passage of the reference wave through the vacuum bore 420 owing to the formation of the bore (vacuum bore 420) through the second sample holding pocket 222. Using the sample holder according to Embodiment 3, an observation by electron holography is hence possible. Moreover, there is no possibility of causing any spill of its content upon formation of the vacuum bore 420, because the first sample holding pocket 221 is sealed by the photo-curing resin layer 310. The sample holder according to Embodiment 3 is hence useful also in this respect.

### <Modifications of the Present Invention>

Embodiments 1 and 2 make reference to the samples for transmission electron microscopes. Similar environment-controlled observations can also be made on even samples for optical microscopes, laser microscopes, scanning electron microscopes, or X-ray microscopes.

In Embodiment 2, the sample holder 500 is described taking, as an example, a side-entry type sample holder for a transmission electron microscope, although the sample holder 500 may be a sample stage for a scanning electron microscope or an X-ray microscope.

In the above embodiments, the bonding of the upper silicon frame 302 and the lower silicon frame 202 with use of the photo-curing resin layer 310 is described. As a sealing material layer other than photo-curing resin, use of, for example, thermosetting epoxy resin and the like can also be possible. In this case, however, there is a need to perform viscosity control and temperature control for several tens of minutes to several hours. On the other hand, photo-curing resin requires a shorter period of time than the thermosetting resin and the like for curing, and is also relaxed in the rigorousness required with respect to the temperature control. For the sample holders according to the present invention, the use of the photo-curing resin layer 310 is advantageous in this respect. Nonetheless, a sealing material layer other than a photo-curing resin layer may also be used insofar as it exhibits a similar effect. In addition, it is to be noted that, even if thermosetting resin or the like is used, the effect can be exhibited to a certain acceptable extent although cumbersomeness increases in temperature control and the like as described above.

In the above embodiments, the sample holders may each include three or more sample holding pockets. By holding, for example, different samples, different liquids or gases, or combinations thereof in the individual sample holding pockets, they may be individually observed. As a still further modification, heaters 230 may be arranged for respective sample holding pockets to control the sample holding pockets such that they are heated to different temperatures. In this case, the same sample and/or the same liquid or gas is held in the individual sample holding pockets, thereby enabling an observation of temperature-dependent differences in behavior.

Electron holography is a technique derived from transmission electron microscopy. In Embodiment 3, it is hence possible, using the same device, to switch whether electron holography is conducted or a general transmission electroscopic observation is conducted. Objects of the observation by transmission electron microscopy include atomic arrangement structures and phase distributions. Objects of the observation by electron holography include electric field distributions and magnetic field distributions. Electron holography needs a longer period of time for obtaining observation data, so that applications may be selected from this viewpoint.

For the above embodiments, specific applications are contemplated as will hereinafter be described. (a) Embodiment 1: Using a transmission electron microscope, an investigation can be made for a phase change or a structure change that may cause a reduction in the efficiency of a catalyst in a liquid or a gas as a sealed closed system. (b) Embodiment 2: Using a transmission electron microscope, an investigation can be made for a phase change or a structure change that may cause a reduction in the efficiency of a catalyst in a liquid or a gas under a flow of the liquid or gas. (c) Embodiment 3: Using a transmission electron microscope, an observation of a potential gradient around a catalyst in a liquid or a gas is possible. Differences in reactivity by heating systems or voltage applications can also be verified. Research can be made with a view to increasing the activity efficiency of a catalyst by controlling the potential gradient in the surrounding.

### DESCRIPTION OF REFERENCE SYMBOLS

100: Separating-membrane-type cell
200: Lower chip
202: Lower silicon frame
204: Lower separating membrane
206: Lower separating membrane window
210: Spacer layer
221: First sample holding pocket
222: Second sample holding pocket
224: Inter-pocket partition
230: Heater
250: Insulating layer
260: Flow channel
300: Upper chip
302: Upper silicon frame
304: Upper separating membrane
306: Upper separating membrane window
310: Photo-curing resin layer
400: Gas or liquid
410: Solid sample
420: Vacuum bore
500: Sample holder
502: Sample holder frame
510: Liquid or gas inlet tube
520: Vacuum sealing packing
530: Cell holding plate
540: Fixing screw
602: Electron source
606: Objective lens
608: Electron biprism
610: Object wave
612: Reference wave
620: Electron biprism wire
622: Opposite electrode
624: Opposite electrode
640: Detector
642: Electron beam interference fringe

1. A sample holder for holding a sample, comprising:
a dividing member dividing an internal space of the sample holder into a first space and a second space;
a member allowing at least either a charged particle beam or an X-ray to pass therethrough toward the first space; and
a sealing material layer arranged above an upper limit of the first space.

2. The sample holder according to claim 1, wherein the first space encloses a liquid or a gas and also encloses the sample.

3. The sample holder according to claim 2, wherein the member is made up of
an upper separating membrane covering at least a part of an upper region over the first space, and
a lower separating membrane forming at least a part of a lower limit of the first space.

4. The sample holder according to claim 3, wherein
the sealing material layer is arranged between the upper separating membrane and the upper limit of the first space, and
the sealing material layer covers the upper limit of the first space and is in contact with an upper surface of the dividing member.

5. The sample holder according to claim 4, wherein the sealing material layer covers an upper limit of the second space, and the upper separating membrane covers further above the upper limit of the second space.

6. The sample holder according to claim 3, wherein the lower separating membrane is arranged at a position where the lower separating membrane is in contact with the lower limit of the first space, and includes a heating member for heating the first space when energized.

7. The sample holder according to claim 3, further comprising:
a lower frame arranged below the lower separating membrane, wherein
the lower frame includes a flow channel that, by communication with the first space, can introduce a fluid into the first space or can exhaust the fluid from the first space.

8. The sample holder according to claim 7, further comprising:
a sample holder frame supporting the lower frame; and
a member fixing a position between the lower frame and the sample holder frame, wherein
the sample holder frame has an inlet tube in communication with the flow channel.

9. The sample holder according to claim 4, wherein
the sealing material layer and the upper separating membrane have openings in communication with the second space, and
the lower separating membrane has an opening in communication with the second space.

10. The sample holder according to claim 9, wherein the first space and the second space have shapes symmetrical to each other with respect to the dividing member.

11. The sample holder according to claim 3, further comprising:
an upper frame arranged below the upper separating membrane;
a lower frame arranged below the lower separating membrane, wherein
the upper frame includes an upper separating membrane window in which the upper separating membrane is exposed at a surface thereof, the surface being on a side opposite to the first space, and
the lower frame includes a lower separating membrane window in which the lower separating membrane is exposed at a surface thereof, the surface being on a side opposite to the first space.

12. The sample holder according to claim 1, wherein the sealing material layer is a photo-curing resin layer.

13. An electron beam instrument comprising:
the sample holder according to claim 1, wherein
the first space encloses a liquid or a gas and also encloses the sample,
the member is made up of
an upper separating membrane covering at least a part of an upper region over the first space, and
a lower separating membrane forming at least a part of a lower limit of the first space,
the sealing material layer and the upper separating membrane have openings in communication with the second space,
the lower separating membrane has an opening in communication with the second space, and
the electron beam instrument includes
an electron source for irradiating both the first space and the second space with an electron beam, and
an electron biprism for causing interference between the electron beam passed through the first space and the electron beam passed through the respective openings.

14. A method for manufacturing the sample holder according to claim 1, comprising:
a step of enclosing a liquid or a gas in the first space and also enclosing the sample in the first space;
a step of arranging an upper frame, the upper frame including the sealing material layer on a surface of an upper separating membrane, above both the first space and the second space; and
a step of curing the sealing material layer, thereby bonding the upper frame at upper limits of the first space and the second space.

15. The method according to claim 14, further comprising:
a step of forming a lower separating membrane on a surface of a lower frame;
a step of forming a spacer layer on a surface of the lower separating membrane;
a step of forming the first space and the second space in a plane of the spacer layer; and
a step of forming, inside the lower frame, a flow channel that, by communication with the first space, can introduce a fluid into the first space or can exhaust the fluid from the first space.

16. The method according to claim 14, further comprising:
a step of forming a lower separating membrane on a surface of a lower frame;
a step of forming a spacer layer on a surface of the lower separating membrane;
a step of forming the first space and the second space in a plane of the spacer layer;
a step of forming, in the sealing material layer and the upper separating membrane, openings in communication with the second space; and
a step of forming, in the lower separating membrane, an opening in communication with the second space.

17. The method according to claim 14, wherein the sealing material layer is a photo-curing resin layer.
